(19) United States
(12) Patent Application Publication
(10) Pub. No.: US 2005/0184785 A1
(43) Pub. Date: Aug. 25, 2005

(54) Combined sample data delay compensation system

(76) Inventor: Ramin Shirani, Morgan Hill, CA (US)

Correspondence Address: SAWYER LAW GROUP LLP, P O BOX 51418, PALO ALTO, CA, 94303, US

(21) Appl. No.: 11/046,021

(22) Filed: Jan. 28, 2005

Related U.S. Application Data
(60) Provisional application No. 60/540,664, filed on Jan. 29, 2004.

(51) Int. Cl. H03K 5/00

(52) U.S. Cl. 327/276

(57) ABSTRACT

A delay compensation technique for two lines or more using multiple sample/hold stages clocked by a multi-phase clock is disclosed. Each line has a delay compensation circuit so as to adjusts the delay of the line to match others. Each phase of the clock samples the input data at certain time intervals, T, where the sampling time intervals are typically equal to a symbol period. By selecting and multiplexing the proper sample/hold data to output in each delay compensation circuit, the outcoming samples are aligned within a time interval. The select signal of each multiplexer selects only one sample/hold output and rotate at a frequency of 1/T. The sample/hold stages not selected at the time can be turned off to save power. The outputs from the multiplexers of the multiple lines can be further fine aligned by continuously moving the multiplexer select signal versus the sampling clocks. The delay compensation technique in accordance with the present invention can be combined with a finite impulse response (FIR) filter using rotating tap weights. Combining the filter and the delay stage together has the advantage of limiting the sample/hold stages the signal needs to go through to one. Also the ON sample/hold stage of the delay compensation circuit in the combined configuration is in fact the FIR stages with rotating tap weights. Therefore in the combination circuit, the delay matching comes at no extra power.

### FIELD OF THE INVENTION

The present invention relates to the field of communications, and in particular, delay mismatch compensation of data signals received from multiple channels, as well as equalization of the signals simultaneously.

### BACKGROUND OF THE INVENTION

Multiple signals traveling through multiple similar communications channels, e.g. twisted pairs or coaxial cables, experience degradation in signal quality as well as different delays even if the multiple channels have similar physical lengths. This phenomenon is simply shown in FIG. 1. FIG. 1 is a diagram of a delay mismatch in output signals of multiple parallel lines. These delay mismatches can be significant, reaching several symbol times at high data rates. In many communication systems, the data signals transmitted at the same time on the multiple channels are required to be processed together at the same time by the receiver to be properly equalized and decoded. Therefore, the received data patterns on each line must be aligned properly, meaning the delay mismatch between the received signals must be cancelled.

For systems performing signal processing all in digital domain where the analog data signal is sampled and digitized at the receiver front-end by an analog to digital converter (ADC), this delay compensation can be done using digital FIFOs (First In First Out) stages. In system where data processing is done in analog domain, this delay matching must be performed in the analog domain. FIG. 2 is a diagram of a conventional implementation of an analog delay mismatch correction circuit 10 using sample/hold (S/H) buffers. A conventional approach to implement an arbitrarily long analog delay is with the use of continuous-time delay elements or pipelined sample and hold stages 12a-12n in the path of analog data signal, and tap the output analog signal from a selected delay element by a multiplexer 14. The problem with this approach is that the analog signal has to go through multiple stages and each stage degrades the signal quality, thus making a long delay line implementation for high resolution systems impractical. In addition, the clock frequency required in this scheme is the same as the incoming symbol rate, and that translates into high-power consumption.

Accordingly, what is needed is a system and method that overcomes the above-identified problems. The system and method should be adaptable to existing technologies, easy to implement and cost-effective. The present invention addresses these needs.

### SUMMARY OF THE INVENTION

A delay compensation technique for two lines or more using multiple sample/hold stages clocked by a multi-phase clock is disclosed. Each line has a delay compensation circuit so as to adjust the delay of the line to match others. Each phase of the clock samples the input data at certain time intervals, T, where the sampling time intervals are typically equal to a symbol period. By selecting and multiplexing the proper sample/hold data to output in each delay compensation circuit, the outcoming samples are aligned within a time interval. The select signal (sel<0:N>) of the multiplexer selects only one sample/hold output at a time and rotates at a frequency of 1/T. The sample/hold stages not selected at the time can be turned off to save power. The outputs from the multiplexers of the multiple lines can be further fine aligned by continuously moving the multiplexer select signal versus the sampling clocks in time.

The delay compensation technique in accordance with the present invention can be combined with a finite impulse response (FIR) filter using rotating tap weights. Combining the filter and the delay stage together has the advantage of limiting the sample/hold stages that the signal needs to go through to one. Also the ON sample/hold stage of the delay compensation circuit in the combined configuration is in fact the FIR stages with rotating tap weights. Therefore in the combination circuit, the delay matching comes at no extra power.

### BRIEF DESCRIPTION OF THE DRAWINGS

FIG. 1 is a diagram of a delay mismatch in output signals of multiple parallel lines.

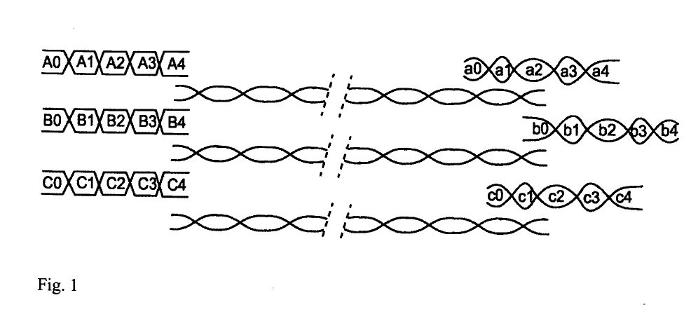

FIG. 2 is a diagram of a conventional implementation of analog delay mismatch correction using sample/hold (S/H) buffers.

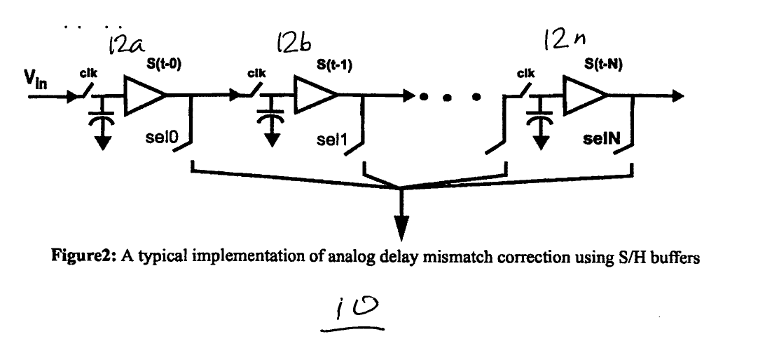

FIG. 3 is a diagram of a conventional architecture of the analog delay mismatch correction circuit in accordance with the present invention.

FIG. 4 is a preferred embodiment of the delay compensation using tri-state buffers.

FIG. 5 illustrates the operation of showing the continuous delay adjustment for a 3-stage delay corrector.

FIG. 6 illustrates the clock gating to generate the imbalanced sampling clock Clk0.

FIG. 7 illustrates the combined delay matched circuit and analog FIR filter.

### DETAILED DESCRIPTION

The present invention relates to the field of communications, and in particular, delay mismatch compensation of data signal received from multiple channels, as well as equalization of the signals simultaneously. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

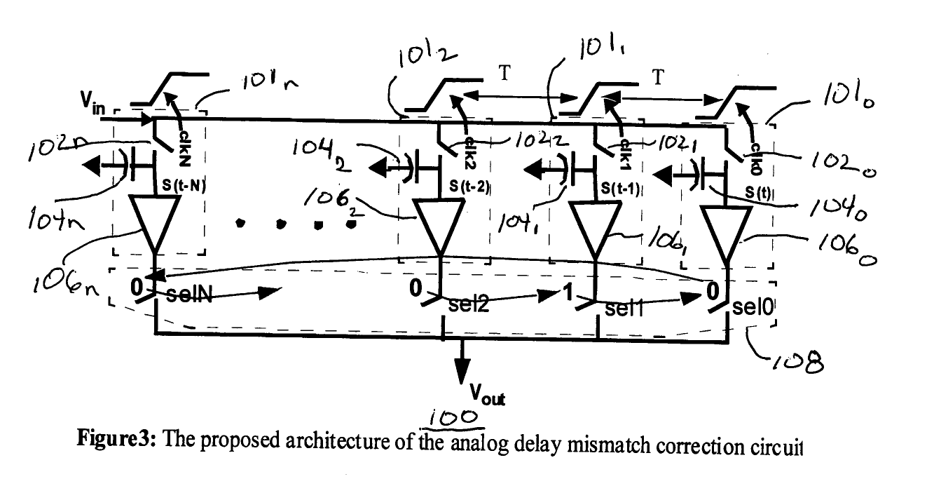

To overcome the drawbacks of the conventional analog delay mismatch cancellation the following design is disclosed. A system and method in accordance with the present invention uses N equal-spaced phases of a clock at 1/N the data symbol rate to obtain the delayed sampled data values, as shown in FIG. 3. FIG. 3 is a diagram of an architecture of the analog delay mismatch correction circuit in accordance with the present invention.

The circuit 100 receives a multiphase clock (Clk₀-Clkₙ). The circuit 100 comprises a plurality of sample/hold stages 106₀-106ₙ. Each of these stages 101 includes a sampling switch 102 sampled to the input voltage, a hold capacitor 104 coupled to the sampling switch 102 and a buffer 106 coupled to the switch 102 and the capacitor 104. Each of the buffers 106₀-106ₙ are coupled together and to a multiplexer 108. The multiplexer 108 provides an output voltage (Vout).

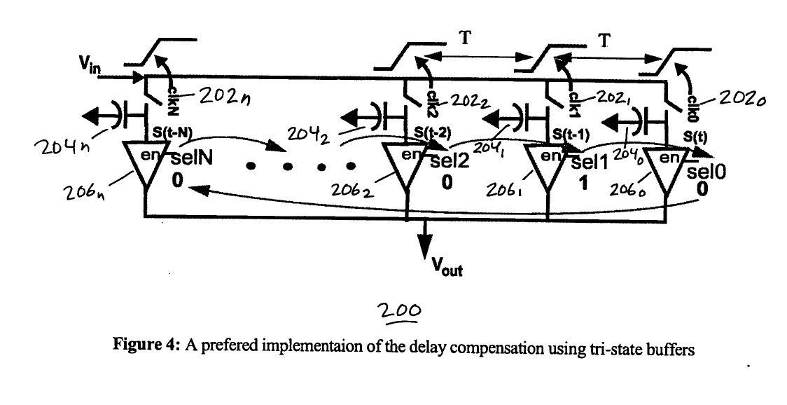

The data samples are sampled with T intervals where in most practical cases T is the symbol time or an integer fraction of that. Therefore the data samples are spaced in time by T steps and each sample stays valid for a period of N*T, provided tracking is performed properly as explanined in the following. In this topology, after initially selecting the proper delay cell to account for the delay mismatch by a N:1 multiplexer 108, the multiplexer's 108 select controls selj rotate at the symbol rate to always connect the correct sampled value to the output as shown. Therefore, although each data sample change every N*T period, the output is always updated at the symbol rate. The major advantage of this topology is that each sampled data value only goes through a single S/H buffer independent of the number of delay stages required, thus there is minimal signal degradation in the sampled analog signals. The clocks used in this scheme are also running at 1/N of the symbol rate, so that saves considerable clocking power. FIG. 4 is a preferred embodiment of the delay compensation circuit 200 using tri-state buffers 206ₒ-206ₙ. FIG. 4 shows another implementation of architecture in FIG. 3, where the outputs of the buffers 206ₒ-206ₙ are directly connected, and each buffer 206 is tri-stated by an enable control “en”. When “en” control is de-asserted, the buffer 206 output is high-impedance, and when asserted, the buffer is activated.

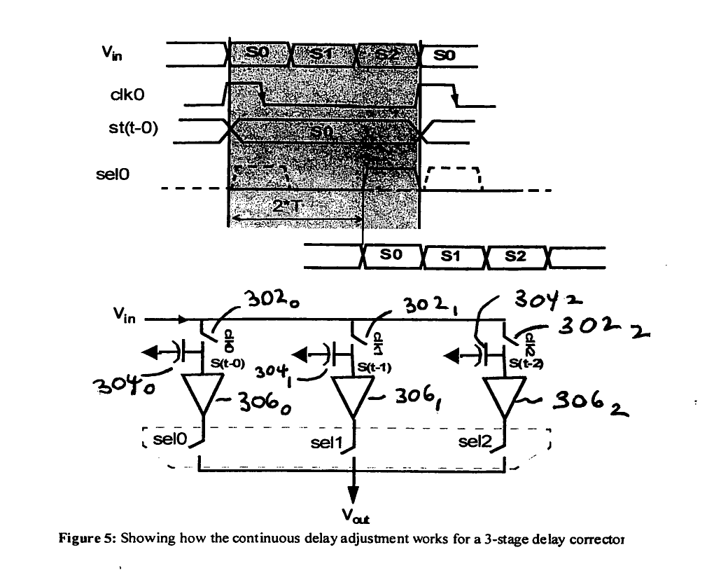

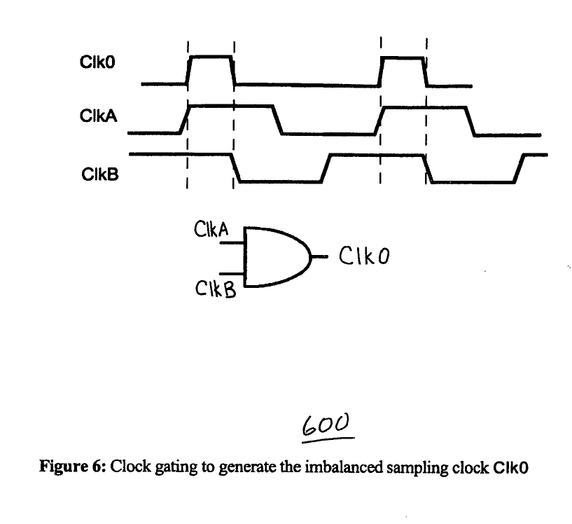

Another major advantage of this design, as shown in FIG. 3 or FIG. 4, is that it offers a continuous delay correction range since each data sample can be valid for a continuous window of N*T. FIG. 5 illustrates the operation of the continuous delay adjustment for a 3-stage delay corrector 300. FIG. 5 shows how the continuous delay correction works for a three stage sampling. The sampling clocks track and sample the corresponding input symbols at the center of the symbols (e.g. adjusted by a data recovery alignment circuit (not shown)) for maximum timing margin as shown in the FIG. 5, where tracking happens when sampling clock is high. In order to maximize the duration that the sample data is valid, the sampling clocks track for only half a symbol period or less if possible, as long as the sampling speed of the sample/hold allows shortening of the tracking window. Any longer tracking time does not offer any advantage but reduces the window the sampled value is valid. This requires sampling clocks with imbalanced duty cycle that can be implemented by logical AND 600 of two skewed clock phases with half-symbol spacing, as shown in FIG. 6.

As shown in a three stage topology, each sampled value is valid for a window of three (3) symbol time, and the select window for each sampled value can slide continuously in this valid window, by as much as two (2) symbol times, to set the required delay at the output. Thus, a delay correction circuit with N sample & hold stages, can provide continuous (N-1) symbol time delay adjustment.

The above topology explained in the two previous figures (i.e. FIG. 3 to FIG. 5) are in fact a delay adjustment stage combined with a gain stage of unity that is selected for each sample in a rotating fashion. This concept can be combined with the implementation of a discrete sampled-data finite impulse response (FIR) filter.

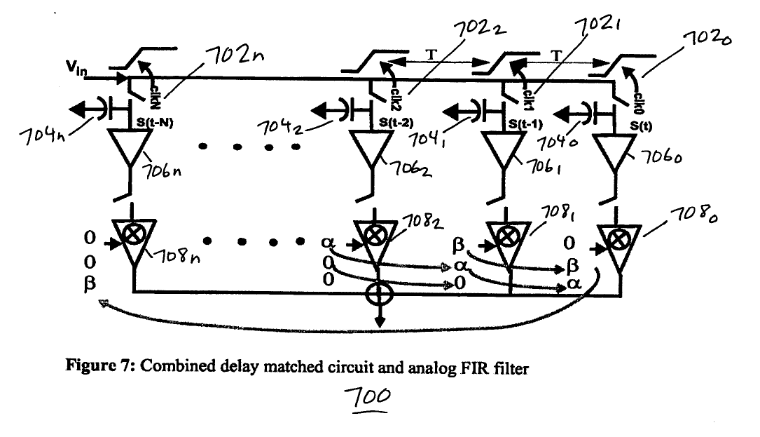

The combination of the delay adjustment stage and the FIR filter is shown in FIG. 7 for a 2-tap FIR filter plus N-2 delay adjustment, using totally N S/H stages and N analog scalers. FIG. 7 illustrates the combined delay matched circuit and analog FIR filter 700. In this embodiment, instead of the select signal rotating at the symbol rate, the filter tap weights, applied to analog scalers 708ₒ-708ₙ following each S/H stage, are rotated at the symbol rate. The outputs of the analog scalars 708ₒ-708ₙ, i.e. weighted analog data samples, are added to form the FIR filtered signal. As an example, where the analog scalers 708ₒ-708ₙ outputs are in form of current, adding analog outputs can be performed using current summing by directly connecting the scalers' outputs. The unused scalers have a tap weight of zero and thus can be turned off to save power. Such a topology is generally applicable to applications where the signals from multiple parallel lines must be equalized and aligned in the analog domain before the analog to digital converter (e.g. as in Gigabit Ethernet over CAT5, CAT6, or CAT7 cable with four twisted-pair wires).

A delay compensation technique for two lines or more using multiple sample/hold stages clocked by a multi-phase clock is disclosed. Each line has a delay compensation circuit so as to adjusts the delay of the line to match others. Each phase of the clock samples the input data at certain time intervals, T, where the sampling time intervals are typically equal to a symbol period. By selecting the proper sample/hold data to output in each delay compensation circuit, the outcoming samples are aligned within a time interval.

Although the present invention has been described in accordance with the embodiments shown, one of ordinary skill in the art will readily recognize that there could be variations to the embodiments and those variations would be within the spirit and scope of the present invention. The delay correction system can be utilized in a variety of environments. For the system can be utilized in the following systems, systems that utilize twisted pairs, coaxial cables, LATS cable or the like. It should be understood that a system and method in accordance with the present invention could be utilized with a variety of other multiple channel wires and that use would be within the spirit and scope of the present invention. Accordingly, many modifications may be made by one of ordinary skill in the art without departing from the spirit and scope of the appended claims.

1. A delay compensation system comprising:
a plurality of sample and hold stages;
a multiphase clock coupled to the plurality of sample and hold stages wherein phase of the clock samples the input data at predefined time intervals; and
a mechanism for selecting one of the sample and hold stage outputs as outcoming data.

2. The system of claim 1 which utilizes a multiplexer for selecting and multiplexing the proper sample and hold stage to ensure that the outcoming signal is aligned within the predetermined time interval, and for providing an output voltage.

3. The system of claim 2 wherein the multiplexer select signal rotates at the symbol rate.

4. The system of claim 1 wherein each of the sample and hold stages comprise a sampling switch, coupled to an input voltage, a hold capacitor coupled to the sampling switch and a buffer coupled to the capacitor and the sampling switch.

5. The system of claim 2 wherein each of the sample and hold stages comprise a sampling switch, coupled to an input voltage, a hold capacitor coupled to the sampling switch and a buffer coupled to the capacitor and the sampling switch.

6. The system of claim 4 wherein each of the buffer outputs are directly connected and each buffer is tri-stated by an enable control signal, wherein when the enable control signal is de-asserted the buffer is high impedance and when the enable control is asserted the buffer is activated.

7. The system of claim 6 wherein the tri-stated enable control signals rotates at the symbol rate.

8. The system of claim 6 which utilizes the tri-state buffer for selecting the proper sampled data to ensure that the outcoming signal is aligned within the predetermined time interval.

9. The system of claim 1 wherein the output data is updated at the symbol rate.

10. The system of claim 1 which includes a delay adjustment stage to allow for continuous delay correction range for the circuit.

11. The system of claim 10 which includes clock gating to generating an imbalanced sampling clock.

12. The system of claim 1 wherein the delay compensation system is provided for each line on a multiple channel wire.

13. The system of claim 12 wherein the multiple channel wire comprises at least a pair of twisted pairs.

14. The system of claim 12 wherein the multiple channel wire comprises a coaxial cable

15. The system of claim 12 wherein the multiple channel wire comprises CAT5, CAT6, CAT7, wherein a cable includes four twisted pair wires.

16. A multiple channel communication system comprising:
a plurality of lines; and
a plurality of delay compensation systems coupled to the plurality of lines; each of the delay compensation system comprising a plurality of sample and hold stages, a multiphase clock coupled to the plurality of sample and hold states wherein phase of the clock samples the input data predefined time intervals and a mechanism for selecting one of the sample and hold state outputs as outcoming data.

17. The system of claim 16 which utilizes a multiplexer for selecting and multiplexing the proper sample and hold stage to ensure that the outcoming signal is aligned within the predetermined time interval and for providing an output voltage.

18. The system of claim 13 wherein the multiplexer select signal rotates at the symbol rate.

19. The system of claim 16 wherein each of the sample and hold stages comprise a sampling switch, coupled to an input voltage, a hold capacitor coupled to the sampling switch and a buffer coupled to the capacitor and switch.

20. The system of claim 17 wherein each of the sample and hold stages comprise a sampling switch, coupled to an input voltage, a hold capacitor coupled to the sampling switch and a buffer coupled to the capacitor and switch.

21. The system of claim 19 wherein each of the hold and sample buffers output are directly connected and each buffer is tri-stated by an enable control signal, wherein when the enable control signal is de-asserted the buffer is high impedance and when the enable control is asserted the buffer is activated.

22. The system of claim 21 wherein the tri-stated enable control signal rotates at the symbol rate.

23. The system of claim 21 which utilizes tri-state buffer for selecting the proper sampled data to ensure that the outcoming signal is aligned within the predetermined time interval

24. The system of claim 16 wherein the output data is updated at the symbol rate.

25. The system of claim 16 which includes a delay adjustment stage to allow for continuous delay correction range for the circuit.

26. The system of claim 25 which includes clock gating to generate an imbalanced sampling clock.

27. The system of claim 26 wherein the clock gating provides clock tracking cycle which is limited to half or less of a symbol period.

28. The system of claim 16 wherein the delay compensation system is provided for each line on a multiple channel wire.

29. The system of claim 28 wherein the multiple channel wire comprises a twisted pair.

30. The system of claim 28 wherein the multiple channel wire comprises a coaxial cable.

31. The system of claim 28 wherein the multiple channel wire comprises and of CAT5, CAT6, CAT7, wherein a cable includes four twisted pair wires.

32. A delay compensation system comprising:
a plurality of sample and hold stages;
a multiphase clock coupled to the plurality of sample and hold stages wherein phase of the clock samples the input data at predefined time intervals; a mechanism for selecting one of the sample and hold stage outputs as outcoming data; and
a finite impulse response filter coupled to the plurality of sample and hold stages.

33. The system of claim 32 wherein a plurality of analog scalers coupled to the plurality of sample and hold stages and an adder form a finite impulse response filter.

34. The system of claim 33 wherein analog scalers include a tap weights which are updated at a symbol rate in a rotation fashion to provide an output.

35. The system of claim 34 which utilizes tap weights rotation for selecting and multiplexing the proper filtered data samples to ensure that the outcoming signal is aligned within the predetermined time interval.

36. The system of claim 33 wherein unused sample and hold stages and analog scalers are turned off to save power.

37. A multiple channel communication system comprising:
a plurality of lines; and
a plurality of delay compensation systems coupled to the plurality of lines; each of the delay compensation system comprising a plurality of sample and hold stages a multiphase clock coupled to the plurality of sample and hold states wherein phase of the clock samples the input data at predefined time intervals; and a finite impulse response filter; wherein the finite impulse response filter comprises a plurality of analog scalers coupled to the plurality of sample and hold stages.

38. The system of claim 37 wherein analog scalers include tap weights which are updated at a symbol rate in a rotation fashion to provide an output.

39. The system of claim 37 wherein unused sample and hold stages and analog scalers are turned off to save power.
